(19) United States
(12) Patent Application Publication
(10) Pub. No.: US 2023/0060860 A1
(43) Pub. Date: Mar. 2, 2023

(54) RESISTIVE MEMORY DEVICE AND PRODUCTION METHOD

(71) Applicant: COMMISSARIAT A L'ENERGIE ATOMIQUE ET AUX ENERGIES ALTERNATIVES, Paris (FR)

(72) Inventors: Christelle CHARPIN-NICOLLE, Grenoble Cedex 09 (FR); Mathieu BERNARD, Grenoble Cedex 09 (FR); Rémy GASSILLOUD, Grenoble Cedex 09 (FR); Thomas MAGIS, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/900,006

(22) Filed: Aug. 31, 2022

(30) Foreign Application Priority Data
Aug. 31, 2021 (FR) 21 08067

(51) Int. Cl. H01L 45/00; H01L 27/24

(52) U.S. Cl. CPC H01L 45/1253; H01L 27/24; H01L 45/145; H01L 45/1675

(57) ABSTRACT

A method for producing a resistive memory cell from a stack of layers having a metal-oxide layer interleaved between first and second electrodes includes forming, within one from among the first and second electrodes, an interlayer material-based electrode interlayer having a selectivity to etching greater than or equal to 2:1 relative to materials of the electrodes. During an etching of the stack, overetching is performed configured to laterally consume, in a horizontal direction, the interlayer material such that the electrode interlayer has a lateral recess greater than or equal to 10 nm.

### TECHNICAL FIELD

The present invention generally relates to a resistive memory device, and more specifically, a non-volatile resistive memory device and its production method.

### STATE OF THE ART

OxRRAM (Oxide-Based Resistive Random Access Memories)-type resistive memories are currently developed for non-volatile applications, with the aim of replacing Flash-type memories. They have, in particular, the advantage of being able to be integrated into interconnecting lines at BEOL (Back-End Of Line)-level of CMOS (Complementary Metal-Oxide-Semiconductor) transistor-based technology. OxRRAM resistive memories are devices comprising, in particular, a metal-oxide layer disposed between two electrodes. The electrical resistance of these devices can be modified by writing and deleting operations. These writing and deleting operations make it possible to make the OxRRAM resistive memory device pass from an LRS (Low Resistive State) to an HRS (High Resistive State), and vice versa.

From cycle to cycle, the resistances of low resistive states LRS and high resistive states HRS do not show a very good reproducibility of performances. A variability of the cycle-to-cycle performances is indeed observed. This variability is particularly important for the high resistive state HRS, inducing a decrease in the programming window, even a total loss of the programming window. This variability problem is today an obstacle to industrialisation.

This concern remains, despite numerous efforts made in the fields of methods for producing resistive memory devices and programming methods.

In a conventional configuration of the resistive memory device, the metal-oxide layer is sandwiched between a first electrode, also called lower electrode, and a second electrode, also called upper electrode.

It has been shown that the lateral reduction of the dimensions of this stack makes it possible to reduce the variability of the electrical performances. This makes it possible, in particular, to limit and to localise the passage of the current through a so-called filamentary or filament zone. The conduction through the metal-oxide layer is thus facilitated.

To contain the filament in a determined zone of reduced width of the metal-oxide layer, a solution consists of only reducing the width of one of the lower or upper electrodes of the stack.

Document US2020/0127197 A1 discloses a resistive memory device formation comprising an upper electrode, reduced in width. A disadvantage of this device and of this formation method is that the reduced size of the upper electrode causes problems in making contact on this upper electrode. The implementation of the device is difficult. It thus appears that other complex and expensive steps are necessary to obtain a device architecture which is utilisable in practice.

An aim of the present invention is to overcome at least partially the disadvantages mentioned above.

An aim of the present invention is to propose a resistive memory device having a reduced HRS variability and which is easy to implement.

Another aim of the present invention is to propose a method for manufacturing such a resistive memory device, having a limited number of steps.

Other aims, features and advantages of the present invention will appear upon examining the following description and the accompanying drawings. It is understood that other advantages can be incorporated.

### SUMMARY

To achieve this aim, according to an embodiment, a method for producing a resistive memory device comprising at least one first electrode and one second electrode material-based electrode is provided, and a metal-oxide layer interleaved between said first and second electrodes in a so-called vertical direction. The device has at least one dimension in width L, preferably greater than or equal to 30 nm in a so-called horizontal direction of a plane perpendicular to the vertical direction.

Advantageously, at least one from among the first and the second electrode is formed so as to comprise an interlayer material-based electrode interlayer having a selectivity S to etching greater than or equal to 2:1, and preferably greater than or equal to 3:1, vis-à-vis electrode materials. The electrode materials are transition metal-based, and the interlayer material is aluminium alloy-based and of said transition metal or of another transition metal.

The method further comprises, after formation of said at least one from among the first and the second electrode comprising the electrode interlayer, an overetching configured to laterally consume, in the horizontal direction, the interlayer material such that the electrode interlayer has a lateral recess strictly greater than 5 nm, and preferably greater than or equal to 10 nm, vis-à-vis the at least one direction in width L, said lateral recess being preferably less than or equal to ⅙*L.

The overetching step thus makes it possible to only reduce a dimension in width Lc of the electrode interlayer, without reducing the dimension in width L of the device. Only one part of the electrode is thus reduced in width, which enables both to localise the creation of the conductive filament during the operation of the resistive memory device, while enabling a good making of contact on another part of the electrode, the dimension in width L of which has not been reduced. In particular, the width of the electrode is reduced in a localised manner, at the interlayer, without the electrode being reduced at the top of the device. The localisation effect of the filament is thus obtained without complexifying the making of contact on the device. By localising the filament by lateral recess, the HRS variability is reduced. Moreover, a lateral recess less than or equal to ⅙*L makes it possible to preserve a formation voltage of the filament, called “forming” voltage, not too high, typically less than 3V, even 2.5V.

A good compromise between the localisation of the filament and the forming voltage is thus obtained. This type of compromise is specific to OxRRAM-type resistive memory devices, and cannot be deduced from solutions implemented for other types of memory, in particular PCRAMs (Phase Change Random Access Memories).

The selectivity S to etching corresponds here to the difference in etching speed between the interlayer material and the electrode materials, during overetching. A selectivity S≥2:1 or S≥3:1 makes it possible de facto to obtain a more significant lateral recess at the electrode interlayer during overetching. The parameters of the overetching step are chosen here, in accordance with the selectivity S, so as to enable a lateral recess of the electrode interlayer of at least 10 nm during overetching.

In the scope of development of the present invention, it has been observed that the perimeter of the device, also called memory point, has after etching, typically of numerous singularities subsequently inducing a random creation of the conductive filament. These singularities extend from the edge of the device over around 2 to 5 nm in the horizontal direction. Thus, a slight involuntary lateral recess which could occur during an etching of the memory point is not sufficient to avoid the impact of the singularities at the periphery of the memory point.

On the contrary, the lateral recess according to the invention is voluntarily done over more than 5 nm and preferably over at least 10 nm to divert the electrode interlayer so as to avoid singularities at the periphery of the memory point. This makes it possible to localise in a controlled and reproducible manner, the creation of the conductive filament during later operating phases of the resistive memory device. This makes it possible to limit the variability of the high resistive state HRS. The programming window of the resistive memory device is stabilised.

Moreover, the overetching step makes it possible to limit the number of total steps of the method. It is not, for example, necessary to provide additional lithography steps. The overetching step can be advantageously carried out in extension and in the continuity of an etching making it possible to obtain a width L device.

According to another embodiment, a resistive memory device is provided, comprising at least one first electrode and one second electrode material-based electrode, and a metal-oxide layer interleaved between said first and second electrodes in a so-called vertical direction. The device has at least one dimension in width L, preferably greater than or equal to 30 nm, in a so-called horizontal direction of a plane perpendicular to the vertical direction.

Advantageously, at least one from among the first and second electrodes comprises an interlayer material-based electrode interlayer having a selectivity to etching greater than or equal to 2:1, and preferably greater than or equal to 3:1, vis-à-vis the electrode materials. The electrode materials are transition metal-based, and the interlayer material is aluminium alloy-based and of said transition metal or of another transition metal.

Advantageously, the electrode interlayer has a lateral recess strictly greater than 5 nm, preferably greater than or equal to 10 nm, vis-à-vis of the at least one direction in width L of the device, said lateral recess being less than or equal to ⅙*L.

Thus, at least one electrode of the device comprises materials having different etching speeds. This differentiation makes it possible to facilitate the production of the device, and in particular to obtain a lateral recess within the electrode, at the interlayer.

The device has a lateral recess at the electrode interlayer of at least 5 nm even of at least 10 nm. An electrode of the device thus advantageously has at least one dimension in width Lc strictly less than the dimension L, partially defined by the lateral recess. The smallest dimension in width of the electrode thus corresponds to the dimension Lc of the electrode interlayer. This advantageously makes it possible to limit the formation of the conductive filament in a localised zone of the metal-oxide layer during the operation of the resistive memory device. The HRS variability is thus reduced. A lateral recess less than or equal to ⅙*L further makes it possible to preserve a correct forming voltage, typically less than 3V even 2.5V. The greatest dimension in width of at least one of the electrodes corresponds to the dimension L of the device. This advantageously makes it possible to facilitate the making of contact for the later connection of the resistive memory device.

### BRIEF DESCRIPTION OF THE FIGURES

The aims, objective, as well as the features and advantages of the invention, will emerge best from the detailed description of embodiments of the latter which are illustrated by the following accompanying drawings, wherein:

FIGS. 1 to 5 schematically illustrate steps of producing a resistive memory device, according to an embodiment of the present invention.

FIG. 6 is an enlargement of the device undergoing manufacture illustrated in FIG. 5.

FIGS. 7 and 8 schematically illustrate steps of producing a resistive memory device, according to an embodiment of the present invention.

FIG. 9 illustrates a device according to another embodiment of the present invention.

FIG. 10 illustrates a device according to another embodiment of the present invention.

The drawings are given as examples and are not limiting of the invention. They constitute principle schematic representations intended to facilitate the understanding of the invention and are not necessarily to the scale of practical applications. In particular, on the principle diagrams, the thicknesses of the different layers and portions, and the dimensions of the patterns are not representative of reality.

### DETAILED DESCRIPTION

Before starting a detailed review of embodiments of the invention, below are stated optional features which can possibly be used in association or alternatively:

According to an example, the formation of said at least one from among the first and second electrodes comprising the electrode interlayer is configured such that the electrode interlayer is directly in contact with the metal-oxide layer.

According to an example, the electrode interlayer is formed directly in contact with the metal-oxide layer. Alternatively, the electrode which comprises the electrode interlayer also comprises an electrode portion located between the interlayer and the metal-oxide layer. Thus, the electrode interlayer is not in direct contact with the metal-oxide layer.

According to an example, the etching of the stack and/or the overetching are done by chlorinated chemistry-based plasma. According to another example, the plasma can be fluorinated chemistry-based, or brominated, or iodinated.

According to an example, during the etching of the stack, at least the first electrode, the second electrode and the metal-oxide layer are etched, preferably on all their respective thicknesses.

According to an example, the overetching is done in continuity of the etching of the stack, by extending a duration of said etching.

According to an example, the first electrode and the second electrode are with the basis, even are made, of the same material. According to another example, the first electrode and the second electrode are with the basis, even are made of, different materials.

The electrode materials are transition metal-based, and the interlayer material is aluminium alloy-based and of said transition metal or of another transition metal. For example, the electrode materials are made of TaN or TiN. According to an example, the transition metal is taken from among Ti, Zr, Hf, Ta, W. The interlayer material is made of TixAly, or ZrxAly, or HfxAly, or TaxAly, or WxAly, with x, y>0.

According to an example, the interlayer material has an Aluminium percentage greater than or equal to 25 at. % (atomic percentage).

According to an example, only the electrode which comprises the electrode interlayer is transition metal-based. The other electrode can be made of another electrically conductive material. “The electrode comprises the interlayer” can mean that the electrode is in contact with the interlayer or that the electrode is constituted, possibly only, of the interlayer. According to an example, the electrode material is TiN-based and the interlayer is ZrAl-based.

According to an example, the overetching is isotropic, such that the lateral recess is formed over a whole perimeter of the electrode interlayer, said electrode interlayer being preferably substantially centred vis-à-vis the device or the stack, projecting into the plane xy.

According to an example, the electrode interlayer has a thickness of between 5 nm and 50 nm, preferably between 5 nm and 30 nm, preferably between 5 nm and 15 nm.

According to an example, the metal-oxide layer is HfO2-based, the electrode materials are Ti- or TiN-based, the interlayer material is TixAly-based, with x, y>0.

According to an example, the electrode interlayer is directly in contact with the metal-oxide layer.

According to an example, the metal-oxide layer forms an overhang or a step with the electrode interlayer.

According to an example, the second electrode comprises a Ti-based oxygen trapping layer. According to an example, the oxygen trapping layer is Hf-based.

According to an example, the electrode interlayer itself forms the at least one electrode from among the first and second electrodes.

According to an example, the at least one electrode from among the first and second electrodes is only constituted of the electrode interlayer.

Except for incompatibility, it is understood that all of the optional features above can be combined so as to form an embodiment which is not necessarily illustrated or described. Such an embodiment is clearly not excluded from the invention.

It is specified that, in the scope of the present invention, the terms “on”, “surmounts”, “covers”, “underlying”, “vis-à-vis” and their equivalents do not necessarily mean “in contact with”. Thus, for example, the deposition of a first layer on a second layer, does not mean compulsorily that the two layers are directly in contact with one another, but means that the first layer covers at least partially the second layer by being either directly in contact with it, or by being separated by it by at least one other layer or at least one other element.

A layer can moreover be composed of several underlayers of one same material or of different materials.

By a substrate, a stack, a layer “based on a material A or “A-based”, this means a substrate, a stack, a layer comprising this material A only or this material A and possibly other materials, for example alloy elements and/or doping elements. Thus, a silicon-based layer means, for example, an Si, n-doped Si, p-doped Si, SiGe layer. A germanium-based layer means, for example, a Ge, n-doped Ge, p-doped Ge, SiGe layer.

By “selective etching vis-a-vis” or “etching having a selectivity vis-à-vis”, this means an etching configured to remove a material A or a layer A vis-à-vis a material B or a layer B, and having an etching speed of the material A greater than the etching speed of the material B. The selectivity is the ratio between the etching speed of the material A and the etching speed of the material B.

Several embodiments of the invention implementing successive steps of the manufacturing method are described below. Except mentioned otherwise, the adjective “successive” does not necessarily imply, even if this is generally preferred, that the steps follow one another immediately, intermediate steps being able to separate them.

Moreover, the term “step” means the embodiment of a part of the method, and can mean a set of sub-steps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term step does not necessarily extend from single and inseparable actions over time and in the sequence of phases of the method.

A preferably orthonormal marker, comprising the axes x, y, z is represented in the appended figures. When one single marker is represented on one same set of figures, this marker applies to all figures of this set.

In the present patent application, the thickness of a layer is taken in a direction normal to the main extension plane of the layer. Thus, a layer typically has a thickness along z. The relative terms “on”, “surmounts”, “under”, “underlying”, “interleaved” refer to positions taken in the direction z.

The terms “vertical”, “vertically” refer to a direction along z. The terms “horizontal”, “horizontally”, “lateral”, “laterally” refer to a direction in the plane xy. Unless explicitly mentioned otherwise, the thickness, the height and the depth are measured along z.

An element located “in vertical alignment with” or “in line with” another element means that these two elements are both located on one same line perpendicular to a plane wherein mainly extends a lower or upper face of a substrate, i.e. on one same line oriented vertically in the figures.

In the scope of the present invention, by horizontal recess or lateral recess, this means a remove of material from a face substantially perpendicular to the plane xy, in a direction normal to this face. The lateral recess of a layer typically forms a step or an overhang vis-à-vis other layers below or above, respectively. The lateral recess can be formed on only one part of the perimeter of the electrode interlayer. The lateral recess can be formed over the whole perimeter of the electrode interlayer. In this latter case, along a transverse cross-section, a lateral recess of each side of the electrode interlayer is observed, that is two lateral recess (which are, in reality, two parts of the same lateral recess). Each lateral recess is thus strictly greater than 5 nm, such that the sum of the lateral recess which can be seen as a transverse cross-section is strictly greater than 10 nm. The lateral recess value is taken locally at the level of said lateral recess. This value does not correspond to the total value of the visible lateral recess, but to each of the visible lateral recess.

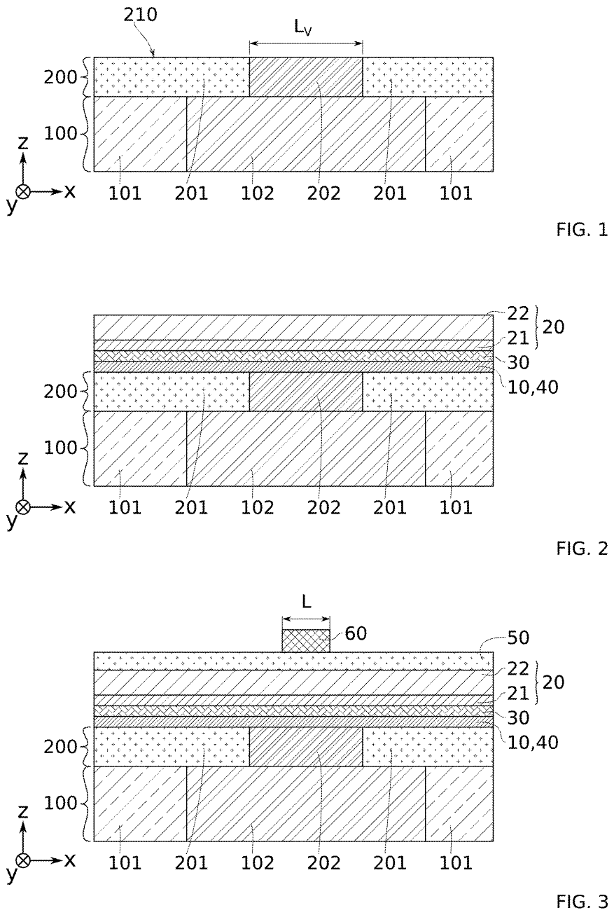

FIGS. 1 to 8 illustrate an embodiment of the method for manufacturing the resistive memory device according to the invention. In the illustrated examples, the resistive memory device takes the form of a memory point of width L. This memory point can be likened to a vertical cylinder comprising the first and second electrodes and the metal-oxide layer. It is typically formed from a stack of layers, by deposition, lithography, etching steps. These different steps are detailed below. Other forms of memory point or of resistive memory device can be fully considered, for example a cube or a parallelepiped. According to a principle of the invention, an interlayer material-based electrode interlayer is inserted in the stack of the memory point, above or below the metal-oxide layer. The electrode, metal-oxide and interlayer materials are preferably chosen such that, under given etching conditions, the etching speed of the interlayer material is greater than the etching speed of the electrode materials, and the etching speed of the electrode materials is greater than the etching speed of metal-oxide. This makes it possible to obtain a narrowing of the memory point at the electrode interlayer.

The resistive memory device is typically formed during so-called BEOL end-of-line technological steps. Thus, as illustrated in FIG. 1, a substrate supporting different metal and via levels is provided. In FIG. 1 of illustration, only the last metal and via levels are represented. The metal level 100 typically comprises metal lines 102 insulated against one another by a dielectric material 101, typically SiO2. The interconnection level 200 typically comprises through vias 202 insulated from one another by a dielectric material 201, typically SiN. The vias 202 typically have a dimension in width Lv along x. The width Lv of the vias 202 is typically between a few tens of nanometres and a few hundred nanometres, for example between 5 and 1000 nanometres, preferably between 10 and 500 nm. A face 210 of the last level 200 is exposed.

As illustrated in FIG. 2, a stack of layers is formed on the exposed face 210. In this example, a first electrode 10, also called lower electrode, is deposited directly in contact with the face 210. This electrode 10 is here fully formed by the electrode interlayer 40. It is preferably TixAly-based, with x, y>0, for example TiAl_{0.3}. The Aluminium percentage of the interlayer 40 can vary, for example between 1% and 99%. Advantageously, the Aluminium percentage of the interlayer is greater than or equal to 25%. This makes it possible to ensure an auto-passivation of this interlayer. The oxygen absorption at the core of the interlayer is thus avoided. This makes it possible to obtain a low and homogenous electrical resistivity for the interlayer. The HRS and/or LRS variability is thus reduced. Zr, Hf, Ta, W can be used in replacement of Ti in the aluminium alloy of the interlayer 40. A metal-oxide layer 30, generally called TMO (Transition Metal Oxide), is then deposited above the electrode interlayer 40. This metal-oxide layer 30 is preferably HfO2-based. A second electrode 20, also called upper electrode, is then formed on the metal-oxide layer 30. This second electrode 20 typically comprises an oxygen trapping layer 21, for example titanium-based, and an electrode layer 22, for example TiN- or TaN-based. The oxygen trapping layer 21 can be directly in contact with the metal-oxide layer 30, as illustrated in FIG. 2. The thickness of the TixAly layer 40 is preferably between 5 nm and 50 nm. The thickness of the HfO2-based metal-oxide layer 30 is preferably between 5 and 15 nm. The thickness of the Ti-based oxygen trapping layer 21 is preferably between 5 and 15 nm. The thickness of the TiN-based electrode layer 22 is preferably between 20 nm and 100 nm.

According to a possibility, the electrode interlayer 40 is formed by a Ti/TixAly or TixAly/Ti bilayer, the total thickness of the two layers being between 5 nm and 15 nm.

FIG. 3 illustrates a lithography step carried out prior to the etching of the stack of electrode and metal-oxide layers. A resin pattern 60 is formed in vertical alignment with the via 202, for example such that said pattern 60 is centred vis-à-vis the via 202, projecting into the plane xy. This pattern 60 defines the shape and the dimensions, projecting into the plane xy, from the desired memory point. It typically has a dimension in width L. A hard mask layer 50, for example SiN- or SiO2-based, can be deposited on the upper electrode 20 before formation of the pattern 60. In a known manner, such an optional layer 50 makes it possible to transfer more faithfully the shape and the dimensions of the pattern 60 in the stack of underlying layers 10, 20, 30, during the following etching. This layer 50 also makes it possible to protect the stack during certain steps, during the resin recess step, commonly referenced by “stripping”.

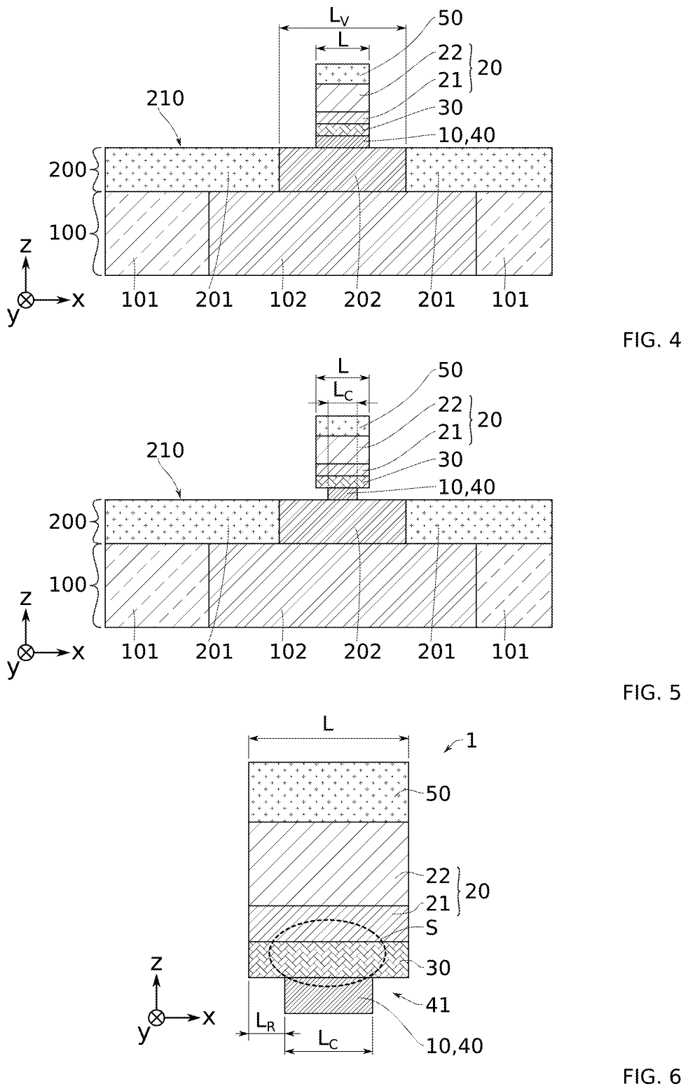

FIG. 4 illustrates the etching of the stack of layers 20, 30, 10, respectively. In this example, the hard mask 50 of width L is represented. Conventionally, the layer 50 is first etched anisotropically along z. The resin pattern 60 is thus removed. Then, all of the stack of the layers 20, 30, 10 is etched anisotropically along z.

This latter etching is done, preferably by chlorinated chemistry plasma. This makes it possible to obtain a stack of width L, comprising, from the face 210, a TixAly-based electrode interlayer 40 forming the lower electrode 10, an HfO2-based metal-oxide layer 30, a Ti-based oxygen trapping layer 21, a TiN-based upper electrode layer 22. Stopping the etching is done, preferably on the exposed via 202, at the face 210.

FIG. 5 illustrates an overetching step making it possible to reduce in width the electrode interlayer 40 only, by preserving the dimension L for the other layers 30, 21, 22 of the stack. During the overetching, the TixAly-based electrode interlayer 40 is etched laterally, along x as a cross-section in FIG. 5, until obtaining a layer 40 of dimension Lc. The overetching is done, typically on either side of the flanks of the stack, such that the layer 40 remains roughly centred vis-à-vis the other layers 30, 21, 22 of the stack. During the subsequent operation of the device, the conductive filament will be formed in a central zone of the metal-oxide layer 30. The reproducibility of formation of the filament during the operation of the device is thus improved. The endurance of the device will thus be improved.

A lateral recess is thus obtained on each side of the layer 40. The overetching is configured such that this lateral recess reaches at least 10 nm along x, on each side of the layer 40. With such a lateral recess, the presence of roughness on the flanks of the upper electrode 20 will no longer be problematic during the creation of the conductive filament. The duration of the overetching can, in particular, be adjusted according to the desired lateral recess. According to an example, the parameters of the overetching are substantially the same as those of the etching. According to another possibility, the parameters of the overetching are modified, for example such that the isotropy of the overetching is increased.

FIG. 6 schematically illustrates the memory point 1 obtained from the overetching. In this example, the lateral recess 41 each have a dimension L_{R}≤10 nm along x. The dimension Lc of the interlayer 40 is equal to L−2.L_{R}. The layer 30 here forms an overhang above the lateral recess 41. During subsequent steps of packaging and of operating the device 1, the conductive filament will be formed in the central zone S of the layer 30. The conductive filament can be formed anywhere in the central zone S of the layer 30, for example on an edge of this central zone S.

This strategy therefore makes it possible to reduce the dimensions which appear or which are useful from the memory point, without imposing an additional dimensional limitation for making contact on the memory point, of dimension L.

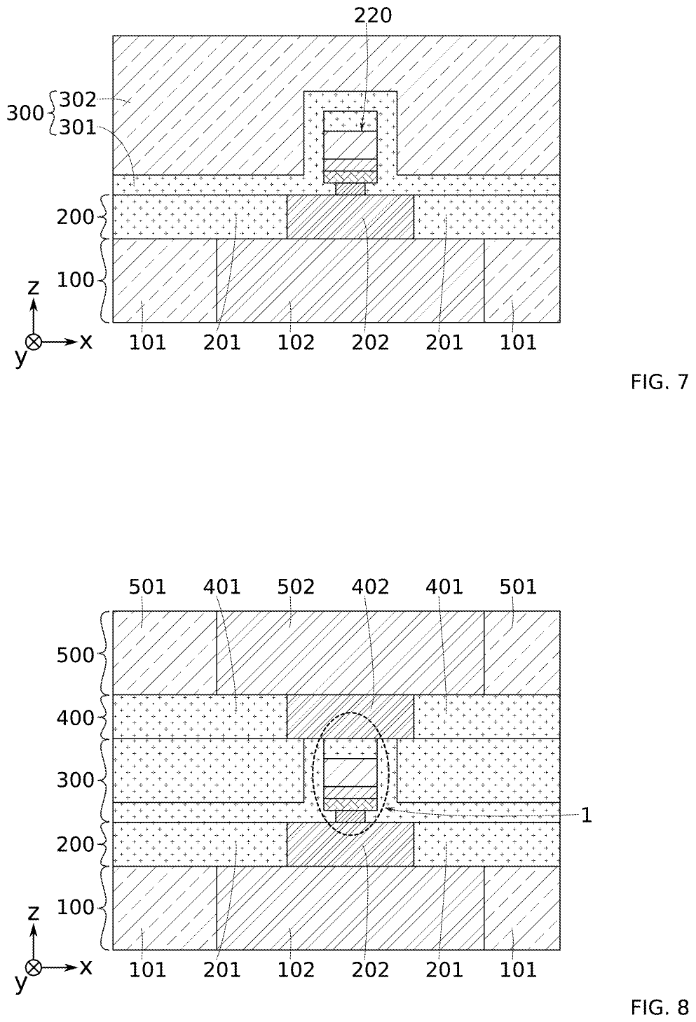

As illustrated in FIG. 7, the memory point is then encapsulated by one or more dielectric layers, for example by a first SiN layer 301, then by a second SiO2 layer 302. The first SiN layer 301 has, for example, a thickness of 30 nm. It is deposited in a conform manner on the memory point. The SiO2 layer 302 can have a thickness of 300 nm. These layers 301, 302 form a dielectric encapsulation layer 300 around the memory point. According to an alternative possibility, this dielectric encapsulation level 300 can be formed by one single layer, for example by an SiO2-based layer.

After deposition of the dielectric layer(s) 301, 302, a planarisation step, for example by mechanical-chemical polishing, is carried out so as to expose an upper face 220 of the upper electrode 20.

As illustrated in FIG. 8, levels of via 400 and of metal 500 are then formed after the planarisation step. This makes it possible to form a metal contact on the memory point 1. The interconnection level 400 typically comprises through vias 402 insulated from one another by a dielectric material 401, typically of SiN. The via(s) 402 is/are preferably centred vis-à-vis the upper electrode 20 of the memory point 1. The metal level 500 typically comprises metal lines 502 insulated from one another by a dielectric material 501, typically of SiO2.

The device 1 illustrated in FIG. 8 is thus fully operational. The top contact formed by the via 402 and the metal line 502, and the bottom contact formed by the via 202 and the metal line 102, can be formed conventionally, without particular dimensional limitations. The device 1 can thus be carried out by standard technological microelectronic steps. The introduction of an interlayer within an electrode of the memory point, coupled with the production of a selective overetching of this interlayer, makes it possible to reduce the apparent dimensions of the memory point in vertical alignment with a central zone of the metal-oxide layer of the memory point. Thus, in operation, the conductive filament will be advantageously formed in a localised and reproducible manner at this central zone.

Other embodiments of the device and of the method according to the invention can be considered.

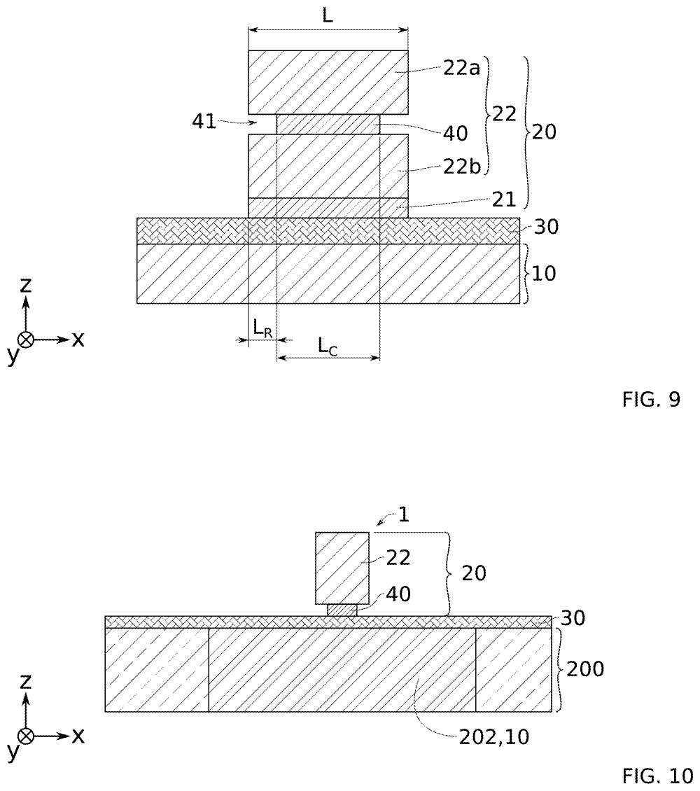

FIG. 9 illustrates a possibility wherein the interlayer 40 is formed within the upper electrode 20, for example within the TiN-based electrode layer 22. The TixAly-based interlayer 40 can thus be located between an upper portion 22a and a lower portion 22b of the upper electrode 22. In this example, the interlayer 40 is not in direct contact with the metal-oxide layer 30.

When the interlayer 40 is located within the upper electrode 20, the metal-oxide layer 30 and/or the lower electrode 10 of the stack do not necessarily have the same dimension in width L as the upper electrode 20.

According to an example of an embodiment illustrated in FIG. 10, the lower electrode 10 is directly formed by the TIN via 202. The metal-oxide layer 30 is therefore deposited directly on the via 202. The etching of the stack is limited to the upper electrode 20. The metal-oxide layer 30 is therefore not reduced in dimensions in the plane xy. In this example, the interlayer 40 is formed within the upper electrode, directly in contact with the metal-oxide layer 30. It is substituted, for example, for the oxygen trapping layer 21 of the upper electrode 20.

Numerous stack configurations including an interlayer 40 forming a narrowing in one and/or the other of the lower 10 and upper 20 electrodes of the resistive memory device 1 are possible. These variants are not necessarily illustrated, but can be easily deduced by combination of the features of the embodiments described.

In any case, such a narrowing formed in the stack makes it possible to localise, in a controlled manner, the formation of the conductive filament in the metal-oxide layer. In particular, the conductive filament is formed in a central zone of the metal-oxide layer located in vertical alignment with the centre of the lower electrode and/or of the upper electrode. This makes it possible to avoid the impact of the edges of the electrodes of the memory point, on the formation of the conductive filament. The variability on the formation voltage of the conductive filament is thus reduced. The reliability of the memory point is advantageously improved. Furthermore, the memory point can have an apparent dimension Lc of a few tens of nanometres, while enabling a facilitated making of contact.

The invention is not limited to the embodiments described above.

1. A method for producing a resistive memory device comprising at least one first electrode and one second electrode based on electrode materials, and a metal-oxide layer interleaved between said first and second electrodes in a vertical direction, said device having at least one width L greater than or equal to 30 nm in a horizontal direction of a plane perpendicular to the vertical direction (z), the method comprising:
forming at least one from among the first and second electrodes so as to comprise an electrode interlayer based on an interlayer material having a selectivity to etching greater than or equal to 2:1 vis-à-vis the electrode materials, the electrode materials being transition metal-based, and the interlayer material being aluminium alloy-based and of said transition metal or of another transition metal, and
after formation of said at least one from among the first and second electrodes comprising the electrode interlayer, performing an overetching configured to laterally consume, in the horizontal direction, the interlayer material such that the electrode interlayer has a lateral recess strictly greater than 5 nm vis-à-vis the at least one width L, said lateral recess being less than or equal to ⅙*L.

2. The method according to claim 1, wherein forming the at least one from among the first and second electrodes comprising the electrode interlayer such that the electrode interlayer is directly in contact with the metal-oxide layer.

3. The method according to claim 1, wherein the overetching is performed using chlorinated chemistry-based plasma.

4. The method according to claim 1, wherein the overetching is isotropic, such that the lateral recess is formed over a whole perimeter of the electrode interlayer projecting into the plane.

5. The method according to claim 1, wherein the electrode interlayer has a thickness between 5 nm and 50 nm.

6. The method according to claim 1, wherein the metal-oxide layer is HfO₂-based, the electrode materials are Ti- or TiN-based, and the interlayer material is TiₓAl_{y}-based, with x, y>0.

7. A resistive memory device comprising:
at least one first electrode and one second electrode based on electrode materials, and
a metal-oxide layer disposed between said first and second electrodes in a vertical direction,
said device having at least one width L greater than or equal to 30 nm in a horizontal direction of a plane perpendicular to the vertical direction, wherein
at least one from among the first and second electrodes comprises an electrode interlayer based on an interlayer material having a selectivity to etching greater than or equal to 2:1, vis-à-vis the electrode materials, the electrode materials being transition metal-based, and the interlayer material being aluminium alloy-based and of said transition metal or of another transition metal, and
the electrode interlayer has a lateral recess strictly greater than 5 nm vis-à-vis the at least one direction in width L, said lateral recess being less than or equal to ⅙*L.

8. The device according to claim 7, wherein the lateral recess extends over a whole perimeter of the electrode interlayer, such that said electrode interlayer is substantially centred vis-à-vis the device, projecting into the plane.

9. The device according to claim 7, wherein the electrode interlayer is directly in contact with the metal-oxide layer.

10. The device according to claim of 7, wherein the metal-oxide layer extends projecting with respect to the electrode interlayer in a direction of the plane.

11. The device according to claim 7, wherein the second electrode comprises a Ti-based oxygen trapping layer.

12. The device according to claim 7, wherein the electrode materials are TiN-based, the metal-oxide layer is HfO₂-based, the interlayer material is TiₓAl_{y}-based, with x, y>0.

13. The device according to claim 7, wherein the at least one electrode from among the first and second electrodes is only constituted of the electrode interlayer.

14. The device according to claim 7, wherein the interlayer material has an aluminium percentage greater than or equal to 25 at. %.

15. The device according to claim 7, wherein the selectivity to etching is greater than or equal to 3:1.

16. The device according to claim 7, wherein the electrode interlayer has a lateral recess strictly greater than 10 nm.

17. The method according to claim 1, wherein the selectivity to etching is greater than or equal to 3:1.

18. The method according to claim 1, comprising performing the overetching to laterally consume, in the horizontal direction, the interlayer material such that the electrode interlayer has a lateral recess strictly greater than 10 nm.

19. The method according to claim 1, wherein the electrode interlayer has a thickness between 5 nm and 15 nm.
